(19) United States
(12) Patent Application Publication
(10) Pub. No.: US 2010/0327586 A1
(43) Pub. Date: Dec. 30, 2010

(54) DRAINAGE, FILTRATION, AND ELECTRICITY GENERATING SYSTEMS AND METHODS

(75) Inventor: Aris MARDIROSSIAN, Potomac, MD (US)

Correspondence Address: NIXON & VANDERHYE, PC, 901 NORTH GLEBE ROAD, 11TH FLOOR, ARLINGTON, VA, 22203, US

(73) Assignee: Technology Patents, LLC, Potomac, MD (US)

(21) Appl. No.: 12/789,616

(22) Filed: May 28, 2010

(51) Int. Cl. F03B 13/08; C02F 1/00; F04B 17/03; B01D 35/26; H05K 13/00; B01D 37/00; H02J 7/34

(52) U.S. Cl. 290/50; 210/170.03; 417/321; 210/85; 29/592.1; 210/767; 210/806; 290/54

(57) ABSTRACT

Certain example embodiments of this invention relate to techniques for collecting run-off and/or draining water from commercial or residential sites, filtering out the liquid, and using the filtered liquid to engage one or more turbines to generate electricity. In certain example embodiments, the one or more turbines are located downstream of filtration, grease-collection, and/or other purification devices. The electricity generated by the one or more turbines may be stored in batteries, serve as a power source for an active drainage/filtration system, used for other activities in or around the site, etc. In certain example embodiments, elements (such as sidewalls, vanes, and/or the like) may be provided upstream of the at least one turbine and downstream of the filtration subsystem, with adjacent elements defining constriction locations therebetween to help accelerate the flow of fluids passing therethrough.

### FIELD OF THE INVENTION

Certain example embodiments of this invention relate to systems and/or methods for drainage, filtration, and/or electricity generation. More particularly, certain example embodiments of this invention relate to techniques for collecting run-off and/or draining water from commercial or residential sites, filtering out the liquid, and using the filtered liquid to engage one or more turbines to generate electricity. In certain example embodiments, the one or more turbines are located downstream of filtration, grease-collection, and/or other purification devices. The electricity generated by the one or more turbines may be stored in batteries, serve as a power source for an active drainage/filtration system, and/or used for other activities in or around the site.

### BACKGROUND AND SUMMARY OF EXAMPLE EMBODIMENTS OF THE INVENTION

The use of drainage systems in connection with commercial and residential sites is known. Indeed, many states throughout the United States have adopted the International Building Code (IBC) in whole, in part, or in a modified form. Subject to some exceptions, the IBC generally requires the use of drainage systems at construction sites, for example, and sets forth guidelines for drainage after the construction is completed. The IBC is an influential code and, because such provisions have been written into it, many local, state, and federal codes have adopted similar provisions pertaining to drainage during and/or after construction.

As alluded to above, some drainage systems are temporary such that they are generally used before and/or during the actual construction. These temporary systems may be removed once construction is complete and/or after the building project has been certified as being up to code. On the other hand, some drainage systems are more permanent, such that they may be retained after construction is complete or such that they may be built into or around the structure(s).

It follows, then, that there are many reasons why drainage systems are used at construction sites. For example, drainage systems may be provided to help reduce the amount of (and sometimes even stop) runoff to public or private areas or lands. Without such drainage systems, runoff may flow onto sidewalks, into fields, adjacent homes, buildings, structures, etc. During construction, runoff may come in the form of silt, dirt, debris, and/or the like.

During construction, it is sometimes possible to have water dumped into a temporarily built pond. However, this often is not possible after the construction is complete. Thus, runoff in the form of these and/or other waste products also may become problematic once construction is complete. At both time periods (e.g., during construction and after construction), the potential environmental impact is large, as the runoff could contaminate the water table, nearby waterways, etc. Negative environmental impact also may be caused more indirectly, e.g., as the runoff may carry away with it valuable topsoil, nutrients, and/or the like.

Another example reason why drainage systems are used is to make up for or otherwise offset changes to the grading that occur during construction. One reason for this is because, as noted above, drainage systems often are needed after construction is completed. In commercial sites such as shopping centers, office buildings, etc., the structure visible at ground level may be thought of as actually being a “second floor.” Oftentimes, beneath the main structure is a labyrinth of pipes, concrete walls, tubes, etc. This system is tied into ground-level drainage systems so that water within a predetermined radius (e.g., from the blacktop abutting the structure to the grass around the structure) is caught and processed therethrough. The system generally catches, stores, and releases the water overtime. Without this storage function, the liquids could overwhelm the local streams when a storm comes, etc. In addition to possibly overwhelming streams, the runoff could include fuel, oil, grease, dirt, etc., resulting from the day-to-day usage of the site.

Still another example reason why drainage systems are used is to slow (and sometimes even stop) erosion that may prematurely damage a newly constructed building or surrounding structures. The threat of accelerated erosion may be a large concern in areas where there is loose-fill dirt, clay, sand, etc. In such cases, drainage systems may help to remove water penetrating a soil mass or to lower the existing ground water table, e.g., so that water is led away and/or allowed to permeate the ground at an appropriate rate (e.g., that slows or stops erosion).

In essence, the drainage may be channeled or otherwise redirected so as to reduce the above-described and/or other problems. Once channeled or generally captured, the liquid may be pumped to a “safe” location, gravity may be used to help redirect the liquid, etc., e.g., along prior flow/previous grade. In some cases, the water may be pooled (e.g., for evaporation), fed into a sewage system (e.g., for handling by a municipal authority or the like), etc. In some instances, the water may be released to the environment at a slower rate, once filtered.

Although drainage systems have been in place for some years and used to help address these and/or other problem areas, the inventor of the instant application has realized that the flowing channeled water itself represents a potentially vast and untapped source of kinetic energy. In that regard, the inventor of the instant application has realized that it would be desirable to harness that energy and put it to a more productive use.

Thus, one aspect of certain example embodiments of this invention pertains to an environmentally sound way of producing “green” energy in connection with drainage systems that already are designed to help protect, and/or reduce the impact on, the surrounding environment. Certain example embodiments thus may produce hydroelectric power by causing drained water to turn one or more turbines located in a drainage system.

In certain example embodiments of this invention, a drainage system is provided. An inlet and an outlet are provided. Piping connects the inlet to the outlet. At least one turbine is located in the piping between the inlet and the outlet, with the at least one turbine including at least one blade arranged to rotate with the flow of liquid through the piping. A power transducer generates electricity based on rotation of the at least one blade of the at least one turbine. A battery may be provided for storing electricity generated by the at least one turbine according to certain example embodiments.

According to certain example embodiments, a filtration subsystem may be provided upstream of the turbine. Such a filtration subsystem may include, for example, a grease separator and at least one filter configured to separate out particulate matter (e.g., a geotextile filter), with the grease separator and the at least one filter being spaced apart from one another.

According to certain example embodiments, the filtration subsystem may include a pump arranged to move filtered particular matter to an at least partially confined area adjacent to a main path of travel for the drainage. A sensor may be configured to monitor the at least partially confined area and generate a signal when the amount filtered particular matter moved thereto meets or exceeds a predetermined threshold.

According to certain example embodiments, a plurality of elements may be provided upstream of the at least one turbine and downstream of the filtration subsystem. Adjacent elements may define constriction locations therebetween to help accelerate the flow of fluids passing therethrough.

In certain example embodiments of this invention, a method of making a drainage system (e.g., at a construction site) is provided.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a schematic view of an electricity generating drainage and filtration system in accordance with an example embodiment;

FIG. 2 is a schematic view of an electricity generating drainage and filtration system that incorporates a filtration pump in accordance with an example embodiment;

FIG. 3 is a schematic view of an electricity generating drainage and filtration system that incorporates plural turbines in accordance with an example embodiment;

FIG. 4 is a schematic view of an electricity generating drainage and filtration system that incorporates a choke location in accordance with an example embodiment; and

FIG. 5 is a flowchart illustrating an example process for generating hydroelectric power in connection with a drainage and filtration system in accordance with an example embodiment.

### DETAILED DESCRIPTION OF EXAMPLE EMBODIMENTS OF THE INVENTION

Certain example embodiments of this invention relate to an environmentally sound way of producing “green” energy in connection with drainage systems that already are designed to help protect, and/or reduce the impact on, the surrounding environment. More particularly, certain example embodiments thus may produce hydroelectric power by causing drained water to turn one or more turbines located in a drainage system. In certain example instances, drainage is captured by a drainage system. That drainage is then filtered in connection with a filtration subsystem. The filtered liquid then may be fed into piping so as to encounter one or more turbines located downstream of the filtration subsystem. Blades of the one or more turbines may be caused to turn, thereby generating hydroelectric power that can be stored or used in any of a variety of applications.

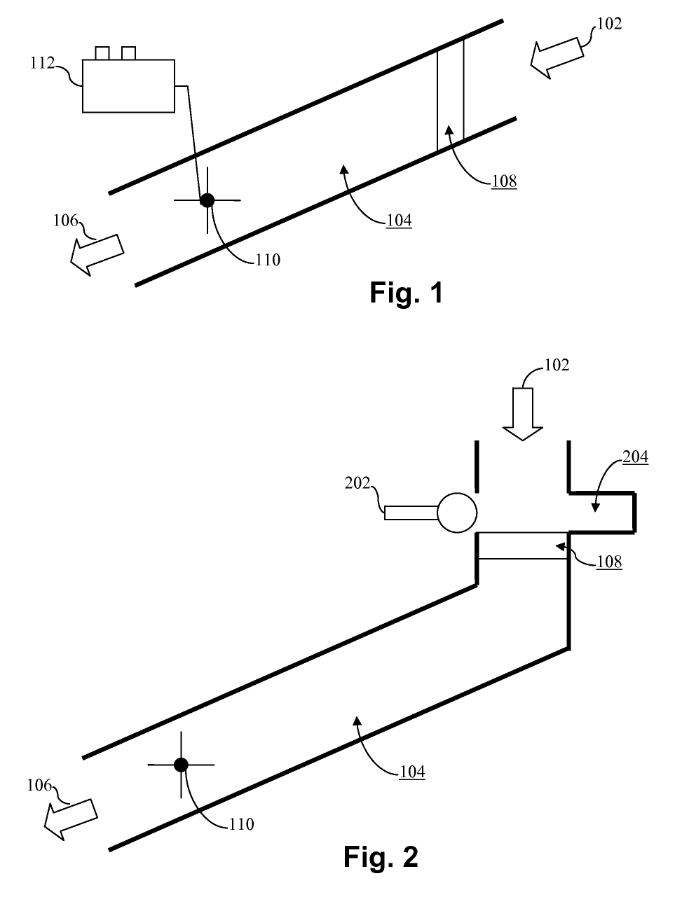

Referring now more particularly to the drawings in which like reference numerals indicate like parts throughout the several views, FIG. 1 is a schematic view of an electricity generating drainage and filtration system in accordance with an example embodiment. The drainage system is provided to collect waste water, runoff, etc. As is conventional, drainage 102 flows into piping or tubing 104 on its way to a safe location 106. The piping 104 conveys the drainage 102 through to a filtration subsystem 108.

The filtration subsystem 108 may include suitable filters such as, for example, charcoal filters, geotextile-based filters, grease separators, and/or the like. See, for example, U.S. Pat. Nos. 4,639,165; 5,133,619; 5,836,115; 6,048,131; and 6,505,996, the entire contents of each of which are incorporated herein by reference. Although a single filter is shown in FIG. 1, the filtration subsystem 108 may comprise multiple of these and/or other kinds of filters. Furthermore, in certain example embodiments, it may be possible to provide one or more of the above-described and/or other filters. In some circumstances, dedicated grease separators may be provided upstream or downstream of one or more geotextile-based filters, the latter of which are sometimes better suited to filtering out particulate matter compared to grease. Systems where multiple different filters are provided may be advantageous in example instances where, for example, it is expected that multiple different kinds of contaminants otherwise would enter into the piping 104. In example embodiments where multiple filters are provided in the context of a larger filtration subsystem 108, the multiple individual filters may be provided in-line but in spaced-apart relation to one another.

One or more turbines 110 are located downstream of filtration subsystem 108. The filtered liquid turns the blades of the turbine(s) 110 to create hydroelectric power. As shown in FIG. 1, the piping 104 is angled downwardly (e.g., at an angle greater than 180 degrees). The presence of the flirtation subsystem 108 and the filters therein may slow the overall flow of water upstream of the turbine. To help compensate for this potential slowdown, the force of gravity related to the angle of the piping 108 may help cause the water to accelerate towards the one or more turbines 110. This, in turn, may help to potentially transfer more energy to the turbine(s) 110 than otherwise would have been possible, even if the filtration subsystem 108 caused no slowdown at all. Of course, the presence and/or amount of angle may vary in different embodiments of this invention. In some cases, the piping 104 in whole or in part may be substantially vertical or completely vertical, e.g., where space and other circumstances allow. Regardless of whether or not the filtration subsystem 108 causes a slowdown, the one or more turbines 110 may be located remote from the filtration subsystem 108, e.g., so that water has chance to pick-up speed.

Each turbine may include one or more rotatable blades. Although FIG. 1 shows a turbine 110 with four blades, different embodiments of this invention may have more or fewer blades. In any event, the length of each blade may be carefully selected such that, in some cases, two opposing blades on the turbine span substantially the entire diameter or distance of the piping 104. In other words, in certain example embodiments, each blade may be sized such that it spans substantially the entire radius (or approximately one half of the distance) of the piping 104. In certain example implementations, a longer blade length may be more desirable to help ensure that even a modest amount or flow of fluid through the piping 104 is likely to come into contact with a blade to cause its movement. At the same time, a blade length that is too long may be undesirable, as the blades may scrape or become jammed if too much unfiltered debris, deposits, calcification, rust, etc., builds up on the inner walls of the piping 104.

The turbine(s) 110 may be mechanically moveable in certain example embodiments. Being able to move the turbine(s) may be desirable in certain example instances so that the turbine(s) 110 become(s) relatively close to the inlet or outlet of the piping 104. This may involve horizontal and/or vertical movement of the turbine(s) 110, e.g., in dependence on the amount of water coming through the piping. For example, it may be advantageous to move the turbine(s) 110 closer to the filtration subsystem 108 when there is a significant flow through the piping 104, whereas it may be advantageous to move the turbine(s) 110 away from the filtration subsystem 108 when a significant flow is lacking. In certain example embodiments, the blades may be extendable and retractable, e.g., in dependence on amount of water coming through piping 104.

Power transducers (not shown in FIG. 1) may help convert the energy to a format storable by one or more batteries 112. Alternatively, or in addition, the generated electricity may be used to power devices more directly, in different embodiments of this invention. In certain example embodiments, a capacitor or capacitive array may be provided to “even out” the generated current so that the electricity may be stored in the battery 112 more efficiently and/or safely, as the current may come in “bursts,” e.g., depending on the relative flows through the piping 104 and the corresponding rotation of the turbine(s) 110. A sensor system and corresponding switch (not shown) may be provided such that the battery 112 is not used until it is charged to at least a predetermined threshold. The battery 112 may be replacable in different example embodiments of this invention and thus may be located remote from the actual turbine(s) 110 and/or piping 104.

FIG. 2 is a schematic view of an electricity generating drainage and filtration system that incorporates a filtration pump in accordance with an example embodiment. FIG. 2 is similar to FIG. 1, except that it includes a more active mechanism to aid the filtration subsystem 108. More particularly, the more active mechanism includes a pump 202. When debris is filtered out by the filtration subsystem 108, it may collect and, over time, negatively impact the performance of the filtration subsystem 108, cause backups with respect to the fluid or otherwise reduce its flow, etc. Thus, a pump 202 may push or otherwise move the filtered out debris out of the direct flow of fluid 102. In the FIG. 2 example embodiment, the pump 202 moves substantially horizontally, and it is located above the filtration subsystem 108. However, it will be appreciated that multiple pumps may be provided in different embodiments, located elsewhere (e.g., between successive filters in the overall filtration subsystem 108), or oriented differently (e.g., not substantially horizontally). The pump 202 itself may be a piston pump or some other sort of pump driven electrically, pneumatically, etc. For example, it may be driven under the flow of the drainage itself if properly oriented, by power generated by the turbine(s) 110 (e.g., as drawn from the battery 112), etc.

The debris may be moved into an at least partially confined area 204. This area 204 may be emptied from time-to-time, manually and/or automatically. For example, in certain example embodiments, a sensor (not shown) may detect when the area 204 is full, is filling up, weighs over a certain amount, has passed a certain height and/or weight threshold, etc. Based on the signal from the sensor, automatic dumping (e.g., to a solid waste area) may be triggered, a signal may be sent to an operator prompting the operator to manually empty the area 204, etc. To aid in the dumping, a wall or other suitable divider may temporarily come down to help seal off the area 204 from the main path of the drainage so that the drainage does not flow into the area 204.

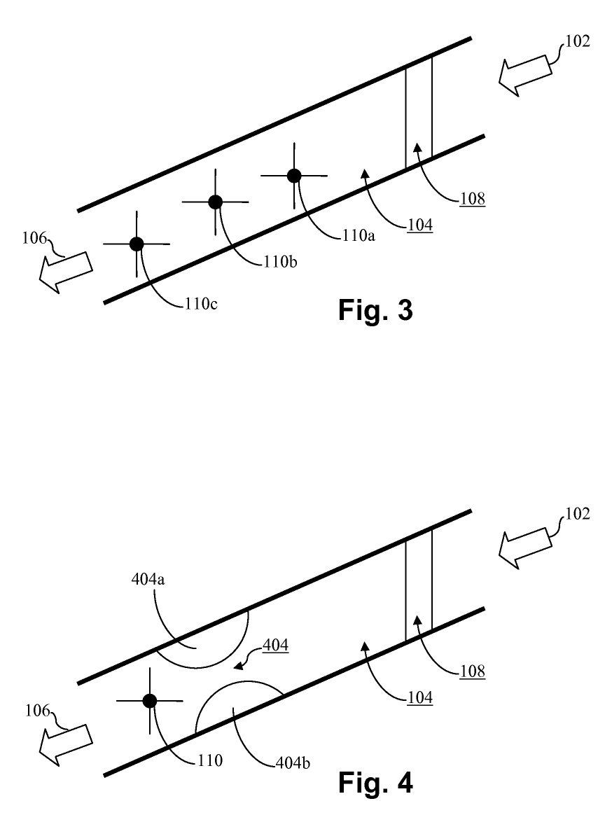

As indicated above, certain example embodiments may incorporate multiple turbines 110. The multiple turbines may be located in serial along the length of the piping 104, in-line or substantially in-line across the diameter or distances of the piping 104, staggered, and/or the like. For instance, FIG. 3 is a schematic view of an electricity generating drainage and filtration system that incorporates plural turbines in accordance with an example embodiment. These turbines 110a-110c are provided in serial along the length of the piping 104. Although three turbines are provided, it will be appreciated that more or fewer turbines may be used in connection with different plural turbine embodiments of this invention.

In embodiments where plural turbines are provided, it would be desirable that it would be advantageous to help ensure that the turbines do not significantly interfere with the operation of adjacent or other turbines provided along the piping 104. Some example problems that may occur include, for instance, the blades coming into contact with one another, creating destructively interfering waves, flows, or currents, etc. Thus, each such turbine may be movable and/or have extendable/retractable blades, as discussed above, to help reduce the likelihood of these and/or other problems occurring. In certain example embodiments, the plural turbines each may be provided in a fixed position so as to reduce the likelihood of these and/or other problems occurring.

In certain example embodiments, the velocity of the liquid may be increased within the piping 104 by virtue of features including, for example, retractable and/or directional vanes and/or side wall elements that help create constricting locations (also sometimes called choke points). In certain example embodiments, the velocity of the liquid may be increased within the channel by virtue of features that produce the Coanda effect. Thus, for instance, both the Venturi effect and the Coanda effect may be used to increase the efficiency of the overall system. The piping 104 of certain example embodiments thus may include features that accelerate or “speed-up” the liquid entering into it, thereby causing the one or more turbines 110 to spin, e.g., in the generation of electricity. In certain example embodiments, the changes in liquid velocity (e.g., increases in liquid velocity) may be influenced by corresponding pressure changes (e.g., pressure drops), e.g., produced in accordance with the Bernoulli principle.

As will be appreciated, the strength of the fluid varies. Indeed, electricity generated from hydroelectric power can be variable at different timescales, e.g., from hour-to-hour, daily, seasonally, etc. Because so much power is generated by higher fluid speed, much of the energy comes in short bursts. Instantaneous electrical generation and consumption preferably remains in substantial balance, e.g., to help maintain grid stability. This variability may present challenges when attempting to incorporate large amounts of hydroelectric power into a grid system. Accordingly, one challenge in power generation is how to maintain a substantially constant density, e.g., to account for changing conditions, with this density factor being related to the effective power produced at the location.

Similar observations as those made above with respect to convention power observation also apply with respect to hydroelectric power used in connection with embodiments of the present invention. Techniques for maintaining an appropriate density with different amounts of drainage therefore may be applied in connection with certain example embodiments of this invention, e.g., as described in greater example below in connection with FIG. 4.

FIG. 4 is a schematic view of an electricity generating drainage and filtration system that incorporates a choke location in accordance with an example embodiment. Various features may influence the velocity of the fluids as they progress through the piping 104 and approach the turbine(s) 110. FIG. 4, for example, includes sidewalls 402a and 402b that create a constriction location 404 or choke point. These elements may in certain example implementations be used to help cause the Venturi effect and/or the Bernoulli principle, e.g., in a controllable manner. As is known, the Venturi effect generally relates to the reduction in fluid pressure that results when a fluid flows through a constricted section of pipe. The fluid velocity increases through the constriction to satisfy the equation of continuity, while its pressure decreases because of conservation of energy. That is, the gain in kinetic energy is balanced by a drop in pressure or a pressure gradient force. Similarly, the Bernoulli principle generally states that an increase in the speed of the fluid occurs simultaneously with a decrease in pressure or a decrease in the fluid's potential energy for inviscid flows. This is accomplished in the FIG. 4 example by causing the liquid to be channeled between the elements 404a and 404b. Given this arrangement, which essentially involves choked flows, the velocity of the liquid will be accelerated as it reaches the vanes 404a and 404b. Accordingly, the velocity of the fluid may be increased to a level sufficient to cause rotation of the turbine(s) 110 in example situations where the amount of drainage is comparatively low. Although sidewall elements are shown in FIG. 4, more or fewer vanes may be provided spaced apart from the walls in the piping 404.

In certain example embodiments, the vanes or sidewall elements may be formed from and/or covered with a smooth material. For example, in certain example instances, a very smooth rubberized material may be used to form such features. Providing a smooth surface may be advantageous in certain example implementations, e.g., to reduce the likelihood of eddy effects being generated, which could sometimes have an impact on the functioning of the turbines, change the characteristics of the constricting locations, alter the pressure gradient(s) produced by the constricting locations, etc. As will be appreciated, such events could negatively impact the performance of the overall system, e.g., by reducing the velocity of the liquid, capping the potential increase in fluid velocity, etc. As such, the materials used to form and/or cover the vanes and/or the sidewall elements may be selected so as to reduce the presence of such eddy effects.

Although the sidewall elements are substantially hemispherical in the FIG. 4 example embodiment (at least when viewed in cross-section), other configurations are also possible. For example, more or less ovular shapes may be used in different example embodiments. Teardrop shapes, for example, also may be used, e.g., for vanes and/or the like. In general, the vanes may be of any size and/or shape, provided that constricting locations (or choke points) are created, in certain example embodiments. The shapes of the sidewall elements may be similar to one-half of a single vane, or they may be provided as differently shaped elements.

As will be appreciated from the description provided above, maintaining density during changing conditions would be advantageous. To help maintain density, some or all of the sidewalls, vanes, turbines, and/or other features may be made directional and/or retractable. Similarly, some or all of the may rotated or otherwise moved so that their respective constricting locations (choke points) are closed. A control system operably connected to the components may coordinate these retracting and/or redirecting actions of the vanes based on the prevailing, changing, and/or other conditions.

Adjustments also may be made by measuring the flow rate, for example, proximate to the turbines. If a suitable velocity is not obtained, the deployment of the features may be adjusted accordingly. Similarly, in addition or in the alternative, electricity production also may be measured and, if too high or too low, the deployment of the features also may be adjusted accordingly. Measurements may be taken upstream and/or downstream of the features and/or turbines. This information also may be used to selectively alter the characteristics of the enabled constricting location(s). For instance, as explained above, features may be selectively deployed to create one or more constricting locations, the size(s) of the constricting location(s) may be adjusted (e.g., by moving, rotating, removing, or otherwise altering the positioning of the vanes), etc. In certain example embodiments, the blades themselves may be temporarily fixed in dependence on such calculations, e.g., so that they do not turn when it is inappropriate to do so. For example, the turbine blades may selectively open/close. It will be appreciated that programmed logic circuitry may be provided so as to perform such calculations and/or direct the components to move accordingly. Such programmed logic circuitry may include a program stored on a computer-readable storage medium.

Generally columnar components may be provided in the piping 104 to further increase the velocity by virtue of the Coanda effect. The Coanda effect generally refers to the tendency of a fluid to be attracted to a nearby surface. The bending of the flow results in its acceleration and, as a result of Bernoulli's principle, pressure is decreased. Thus, the incorporation of such components may be used to further increase the velocity of the liquid. As above, these columnar elements may be made retractable and/or movable. Furthermore, any number of elements may be present in different locations in different example embodiments of this invention. For example, such elements may be located past the constricting locations (or choke points). However, these elements may be moved up towards, in, or in front of the constricting locations (or choke points). In certain example embodiments more or fewer elements may be implemented. In certain example embodiments, a single Coanda effect producing element may be located upstream of the constricting locations.

Regardless of whether any fluid-accelerating features are provided, certain example embodiments may be designed such that filtered water is released into the surrounding environment at a predetermined and controlled rate. This rate may be selected to match the rate at which water otherwise would be absorbed by the area had the site not been built. In other words, according to certain example embodiments, the release rate may be made to match the predetermined or calculated porosity of the site so as to reduce the overall negative impact on the site. In some cases, the rate may be specified by a governmental authority. A system of locks may be provided to control the release rate in certain example embodiments of this invention. However, prior to the release of the water, one or more turbines are provided so as to generate hydroelectric power that may be used for any number of different purposes. Any such turbines may be located proximate to the ultimate release area, either upstream or downstream of any locks and downstream of any filters.

In certain example embodiments, grease and particulate matter may be collected in one or more separate, at least partially enclosed locations. This material may be periodically pumped out (e.g., monthly, yearly, etc.) and transported to another area for safe disposal. At the same or a different time, filters may be replaced, as needed.

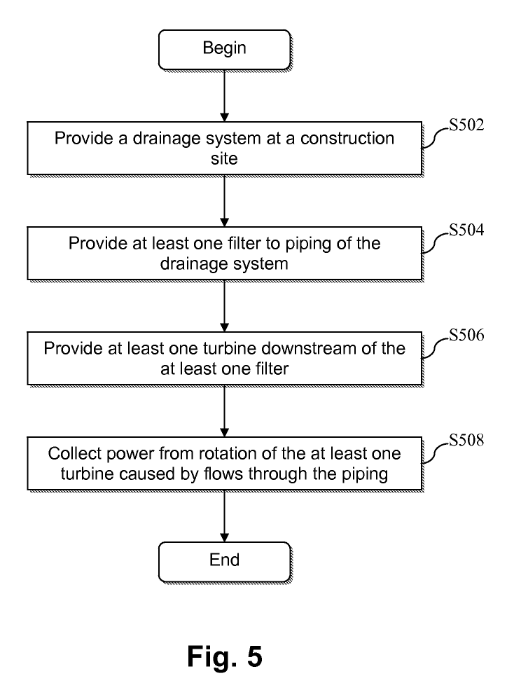

FIG. 5 is a flowchart illustrating an example process for generating hydroelectric power in connection with a drainage and filtration system in accordance with an example embodiment. A drainage system at a construction site is provided in step S502. At least one filter is provided to piping of the drainage system in step S504. The at least one filter may be a part of a larger filtration subsystem and may include, for example, geotextile-based filters. In step S506, at least one turbine is provided downstream of the at least one filter. The at least one turbine is oriented such that liquid flowing through the piping of the system will engage blades thereof, causing them to rotate. In step S508, power is collected from the rotation of the at least one turbine caused by flows through the piping. This harvested hydroelectric power may be stored in a battery or batteries and/or used to power one or more external devices. In certain example embodiments, harvested hydroelectric power may be used to power the aspects of the system such as, for example, components of the filtration subsystem, etc.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A drainage system, comprising:
an inlet for receiving drainage and an outlet;
piping connecting the inlet to the outlet;
at least one turbine located in the piping between the inlet and the outlet, the at least one turbine including at least one blade arranged to rotate with the flow of liquid through the piping; and
a power transducer for generating electricity based on rotation of the at least one blade of the at least one turbine.

2. The system of claim 1, further comprising a filtration subsystem provided upstream of the turbine.

3. The system of claim 2, wherein the filtration subsystem includes a grease separator.

4. The system of claim 2, wherein the filtration subsystem includes at least one geotextile filter.

5. The system of claim 2, wherein the filtration subsystem includes a grease separator and at least one filter configured to separate out particulate matter, the grease separator and the at least one filter being spaced apart from one another.

6. The system of claim 2, further comprising a battery for storing electricity generated by the at least one turbine.

7. The system of claim 2, further comprising a plurality of turbines located in serial throughout the tubing.

8. The system of claim 2, wherein the filtration subsystem includes a filter configured to separate out particulate matter and a pump arranged to move filtered particular matter to an at least partially confined area adjacent to a main path of travel for the drainage.

9. The system of claim 8, wherein the pump is powered by electricity generated by the power transducer.

10. The system of claim 8, further comprising a sensor configured to monitor the at least partially confined area and generate a signal when the amount filtered particular matter moved thereto meets or exceeds a predetermined threshold.

11. The system of claim 2, further comprising a plurality of elements provided upstream of the at least one turbine and downstream of the filtration subsystem,
wherein adjacent elements define constriction locations therebetween that accelerate the flow of fluids passing therethrough.

12. The system of claim 11, wherein the elements include sidewall elements provided on generally opposing inner surfaces of the piping.

13. The system of claim 11, wherein the elements include vanes.

14. A method of making a drainage system at a construction site, the method comprising:
providing an inlet for receiving drainage and an outlet;
providing piping connecting the inlet to the outlet;
providing at least one turbine in the piping between the inlet and the outlet, the at least one turbine including at least one blade arranged to rotate with the flow of liquid through the piping; and
providing a power transducer for generating electricity based on rotation of the at least one blade of the at least one turbine.

15. The method of claim 14, further comprising providing a filtration subsystem upstream of the turbine.

16. The method of claim 15, wherein the filtration subsystem includes a grease separator.

17. The method of claim 15, wherein the filtration subsystem includes a grease separator and at least one filter configured to separate out particulate matter, the grease separator and the at least one filter being spaced apart from one another.

18. The method of claim 15, further comprising providing a battery for storing electricity generated by the at least one turbine.

19. The method of claim 15, further comprising providing a plurality of turbines located in serial throughout the tubing.

20. The system of claim 15, further comprising providing a plurality of elements upstream of the at least one turbine and downstream of the filtration subsystem,
wherein adjacent elements define constriction locations therebetween that accelerate the flow of fluids passing therethrough.
